(19) United States
(12) Patent Application Publication
(10) Pub. No.: US 2025/0267817 A1
(43) Pub. Date: Aug. 21, 2025

(54) STORAGE DEVICE COOLING AIR VENTILATION FEATURES

(71) Applicant: Sandisk Technologies, Inc., Milpitas, CA (US)

(72) Inventors: MyungJin Kim, Santa Clara, CA (US); Fu Xing Chan, Penang (MY); Li Chen, Sunnyvale, CA (US); Daniel Oh, San Jose, CA (US); Leroy Fong, Irvine, CA (US); Hedan Zhang, Santa Clara, CA (US)

(21) Appl. No.: 18/583,458

(22) Filed: Feb. 21, 2024

(51) Int. Cl. H05K 7/20; G06F 1/20; H05K 5/00

(52) U.S. Cl. CPC H05K 7/20145; G06F 1/20; H05K 5/0026; H05K 7/2039

(57) ABSTRACT

In the context of an electronic device such as a solid-state storage drive, use of an enclosure cover including an inlet port through a first lateral sidewall and a corresponding cooling duct coincident with first inlet port enables directing of airflow laterally to below the cover to a printed circuit board housed therein. To further augment device cooling within specification-dictated restrictions, a row of ventilation slots may be used for directing additional lateral airflow over the outer surface of the cover. Still further, interfacing tooth structures in the cover and corresponding base enable cost-effective end-to-end airflow through the device by avoiding machining steps during manufacturing, while still mitigating risk of electrostatic discharge.

### FIELD OF EMBODIMENTS

Embodiments of the invention may relate generally to electronic devices such as solid-state storage devices, and particularly to cooling air ventilation features.

### BACKGROUND

Enterprise solid-state storage devices, or solid-state drives (SSDs), are commonly used in client, hyperscale and enterprise compute environments. Since SSDs are made from flash memory (e.g., NAND (NOT AND) flash memory), they can be built in many different form factors and are typically associated with industry standard form factors and corresponding specifications and protocols. For example, a family of specifications referred to as Enterprise and Datacenter Standard Form Factor (EDSFF) were developed to address the concerns of data center storage. For example, EDSFF E3 is a family of form factors designed to update and replace the traditional U.2 2.5-inch form factor in servers and storage systems, and were largely designed for future servers and storage systems. The primary usage of E3 is for SSDs and/or storage class memory, but E3 is big enough to accommodate a broader range of device types (for non-limiting examples, accelerators or network interface cards). It is well-known that electronic devices generally and SSDs in particular dissipate power in the form of heat, which requires significant cooling and related costs.

Any approaches that may be described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

### BRIEF DESCRIPTION OF THE DRAWINGS

Embodiments are illustrated by way of example, and not by way of limitation, in the figures of the accompanying drawings and in which like reference numerals refer to similar elements and in which:

FIG. 1 is a block diagram illustrating a solid-state drive (SSD), according to an embodiment;

FIG. 2A is a perspective view illustrating SSD device cooling duct features, according to an embodiment;

FIG. 2B is a perspective view illustrating SSD device cooling duct features, according to an embodiment;

FIG. 3A is a top perspective view illustrating a top cover of SSD device of FIGS. 2A-2B, according to an embodiment;

FIG. 3B is a top perspective view illustrating a top cover of SSD device of FIGS. 2A-2B, according to an embodiment;

FIG. 3C is a bottom perspective view illustrating a top cover of SSD device of FIGS. 2A-2B, according to an embodiment;

FIG. 3D is a bottom perspective view illustrating a top cover of SSD device of FIGS. 2A-2B, according to an embodiment;

FIG. 4A is a perspective view illustrating a bottom base of SSD device of FIGS. 2A-2B, according to an embodiment;

FIG. 4B is a perspective view illustrating a bottom base of SSD device of FIGS. 2A-2B, according to an embodiment;

FIG. 5A is a perspective view illustrating an SSD device assembly defining cross-sections, according to an embodiment;

FIG. 5B is a first cross-sectional perspective view illustrating the SSD device assembly of FIG. 5A, according to an embodiment;

FIG. 5C is a second cross-sectional perspective view illustrating the SSD device assembly of FIG. 5A, according to an embodiment;

FIG. 5D is a third cross-sectional perspective view illustrating the SSD device assembly of FIG. 5A, according to an embodiment;

FIG. 5E is a fourth cross-sectional perspective view illustrating the SSD device assembly of FIG. 5A, according to an embodiment;

FIG. 6 is a perspective view illustrating an SSD device assembly with cooling ventilation features, according to an embodiment;

FIG. 7A is a perspective view illustrating a top cover of SSD device of FIG. 6, according to an embodiment;

FIG. 7B is a perspective view illustrating the top cover of SSD device of FIG. 6, according to an embodiment;

FIG. 8A is a perspective view illustrating a bottom base of SSD device of FIG. 6, according to an embodiment;

FIG. 8B is a perspective view illustrating the bottom base of SSD device of FIG. 6, according to an embodiment;

FIG. 9A is a perspective view illustrating a first end of an SSD device assembly with cooling ventilation features, according to an embodiment;

FIG. 9B is a perspective view illustrating a second end of an SSD device assembly with cooling ventilation features, according to an embodiment;

FIG. 10A is a perspective view illustrating the first end of a top cover of SSD device assembly of FIGS. 9A-9B, according to an embodiment;

FIG. 10B is a perspective view illustrating the second end of the top cover of SSD device assembly of FIGS. 9A-9B, according to an embodiment;

FIG. 11A is a perspective view illustrating the first end of a bottom base of SSD device assembly of FIGS. 9A-9B, according to an embodiment;

FIG. 11B is a perspective view illustrating the second end of the bottom base of SSD device assembly of FIGS. 9A-9B, according to an embodiment;

FIG. 12A is an end perspective view illustrating a solid-state storage device, according to an embodiment;

FIG. 12B is a side perspective view illustrating the solid-state storage device of FIG. 12A, according to an embodiment;

FIG. 12C is a cross-sectional perspective view illustrating the solid-state storage device of FIG. 12A, according to an embodiment; and

FIG. 13 is a flow diagram illustrating a method of assembling a data storage device, according to an embodiment.

### DETAILED DESCRIPTION

Generally, approaches to electronic device cooling air ventilation features, such as for solid-state drives, are described. In the following description, for the purposes of explanation, numerous specific details are set forth to provide a thorough understanding of the embodiments of the invention described herein. It will be apparent, however, that the embodiments of the invention described herein may be practiced without these specific details. In other instances, well-known structures and devices may be shown in block diagram form to avoid unnecessarily obscuring the embodiments of the invention described herein.

### INTRODUCTION

### Terminology

References herein to “an embodiment”, “one embodiment”, and the like, are intended to mean that the particular feature, structure, or characteristic being described is included in at least one embodiment of the invention. However, instances of such phrases do not necessarily all refer to the same embodiment,

The term “substantially” will be understood to describe a feature that is largely or nearly structured, configured, dimensioned, etc., but with which manufacturing tolerances and the like may in practice result in a situation in which the structure, configuration, dimension, etc. is not always or necessarily precisely as stated. For example, describing a structure as “substantially vertical” would assign that term its plain meaning, such that the sidewall is vertical for all practical purposes but may not be precisely at 90 degrees throughout.

While terms such as “optimal”, “optimize”, “minimal”, “minimize”, “maximal”, “maximize”, and the like may not have certain values associated therewith, if such terms are used herein the intent is that one of ordinary skill in the art would understand such terms to include affecting a value, parameter, metric, and the like in a beneficial direction consistent with the totality of this disclosure. For example, describing a value of something as “minimal” does not require that the value actually be equal to some theoretical minimum (e.g., zero), but should be understood in a practical sense in that a corresponding goal would be to move the value in a beneficial direction toward a theoretical minimum.

### Context

Recall that enterprise storage solutions such as solid-state drives (SSDs) are commonly used in client, hyperscale and enterprise compute environments, and that a family of specifications referred to as Enterprise and Datacenter Standard Form Factor (EDSFF) were developed to address the concerns of data center storage. Furthermore, the specifications for the EDSFF E3 (or simply “E3”) family of form factors set forth constraints related to various structures corresponding to an E3 storage device, such as what portions of a device sidewall must be reserved for grounding surfaces and riding surfaces (e.g., related to device handling/installation). In view of the cooling needs of an SSD, and further in view of the limited structural space available for cooling features on an SSD, efficiently and inexpensively cooling an SSD remains a challenge, especially in the context of high-velocity airflow such as in high-performance datacenter and server systems.

### Electronic Storage Device Cooling Features

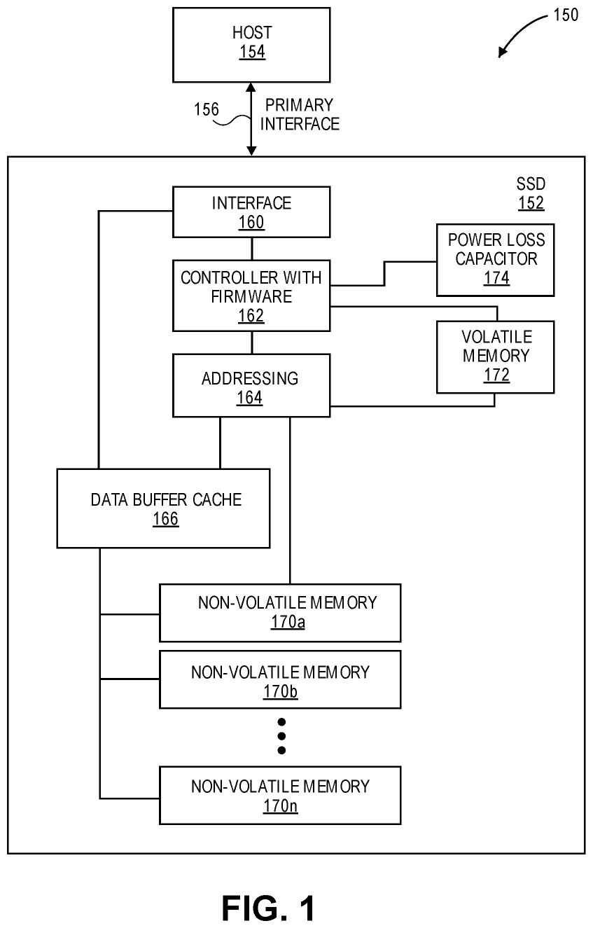

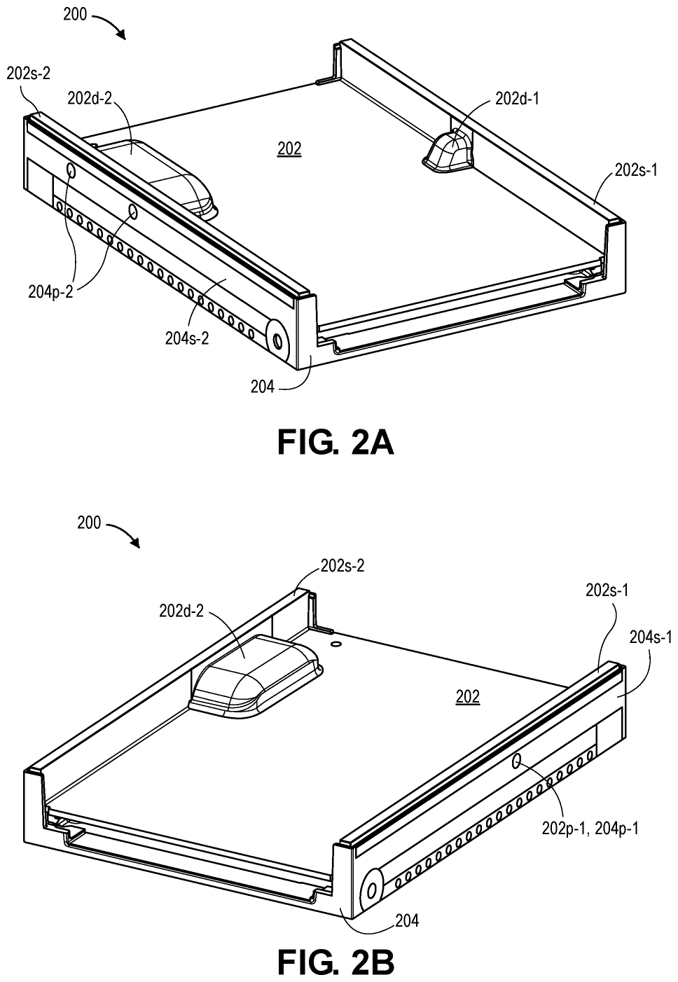

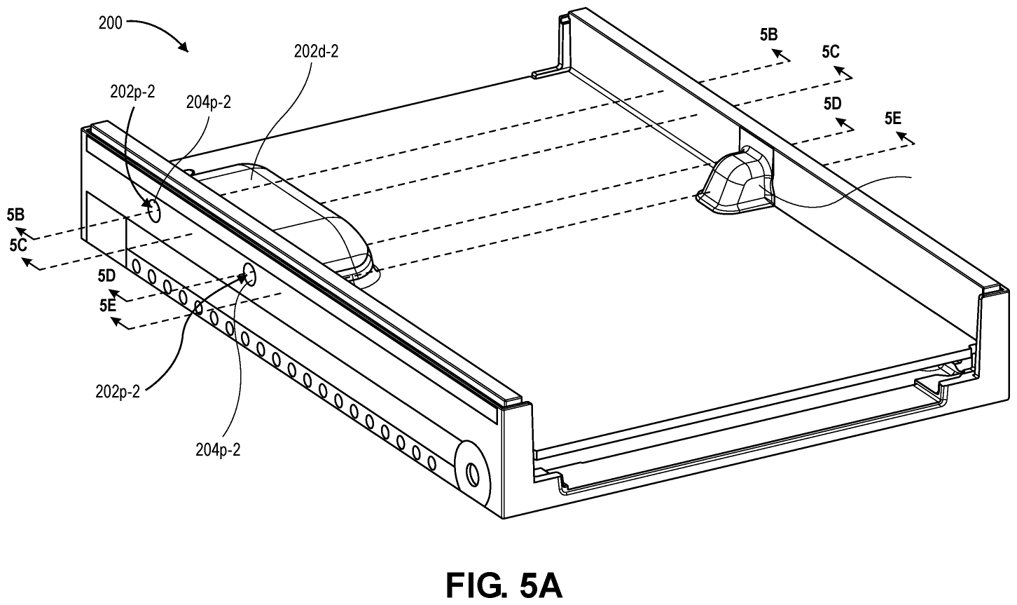

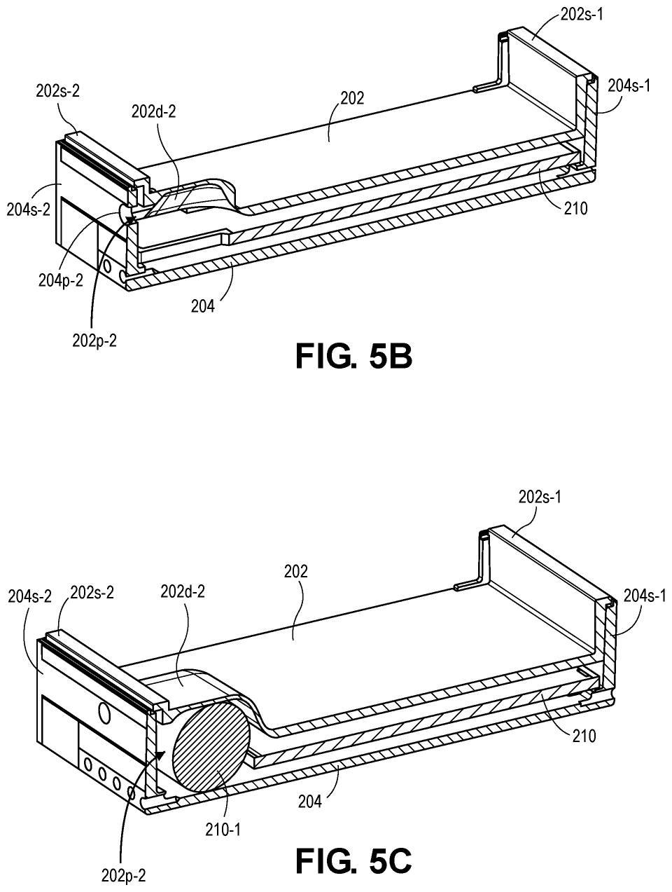

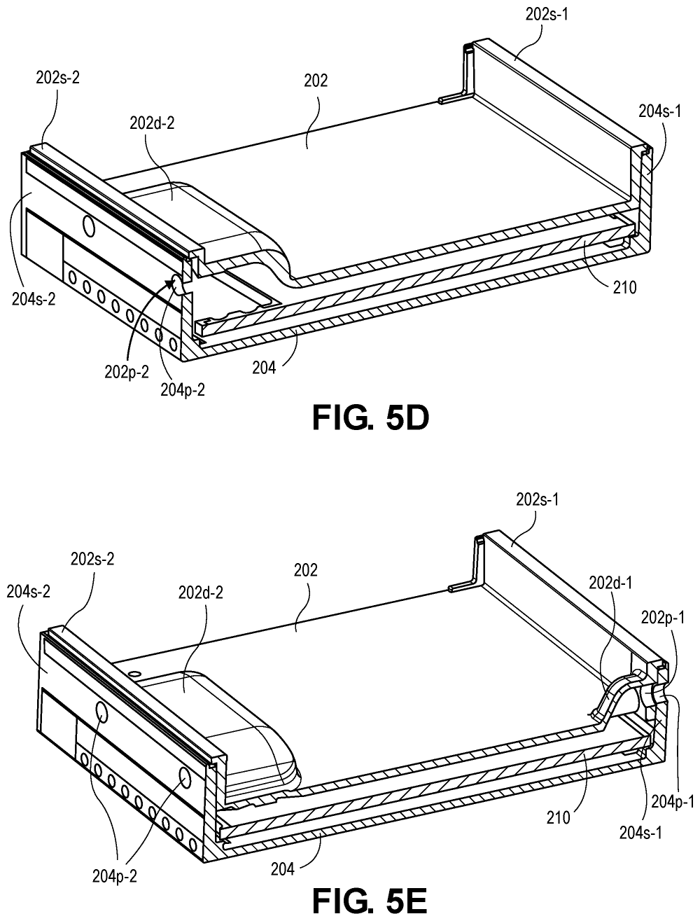

FIG. 2A is a perspective view illustrating SSD device cooling duct features, and FIG. 2B is a perspective view illustrating SSD device cooling duct features, both according to embodiments. An electronic storage device such as illustrated storage device 200 is configured to comprise one or more printed circuit board (PCB) (PCB 210 of FIGS. 5B-5E; see also, e.g., the components of SSD 152 of FIG. 1) within a device enclosure described hereafter. According to an embodiment, storage device 200 comprises a PCB including non-volatile memory. Similarly, and according to an embodiment, storage device 200 comprises a PCB including NAND (NOT AND) flash memory. Furthermore, and according to an embodiment, storage device 200 is a solid-state drive (SSD) storage device (see, e.g., SSD 152 of FIG. 1).

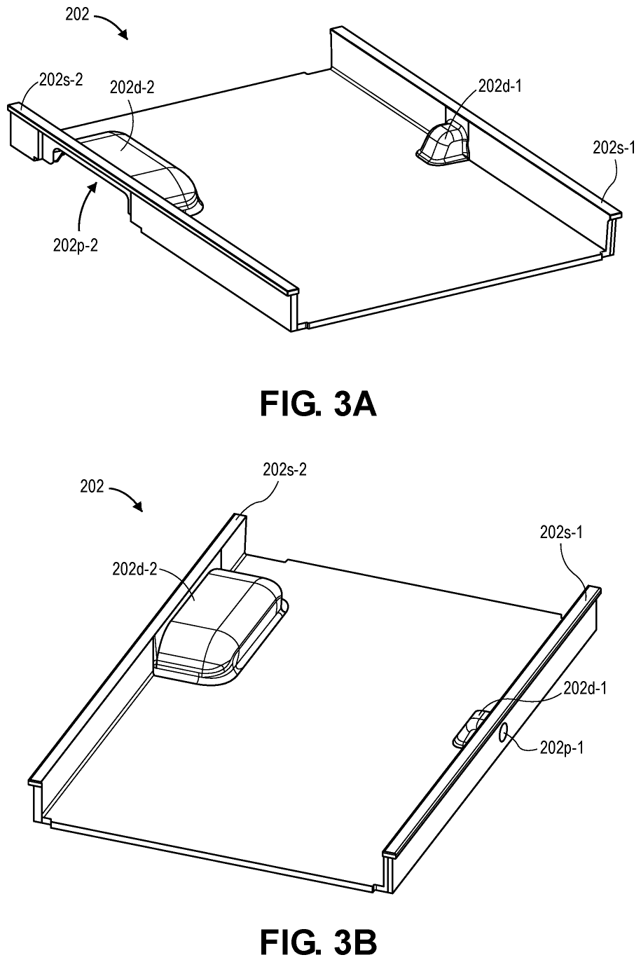

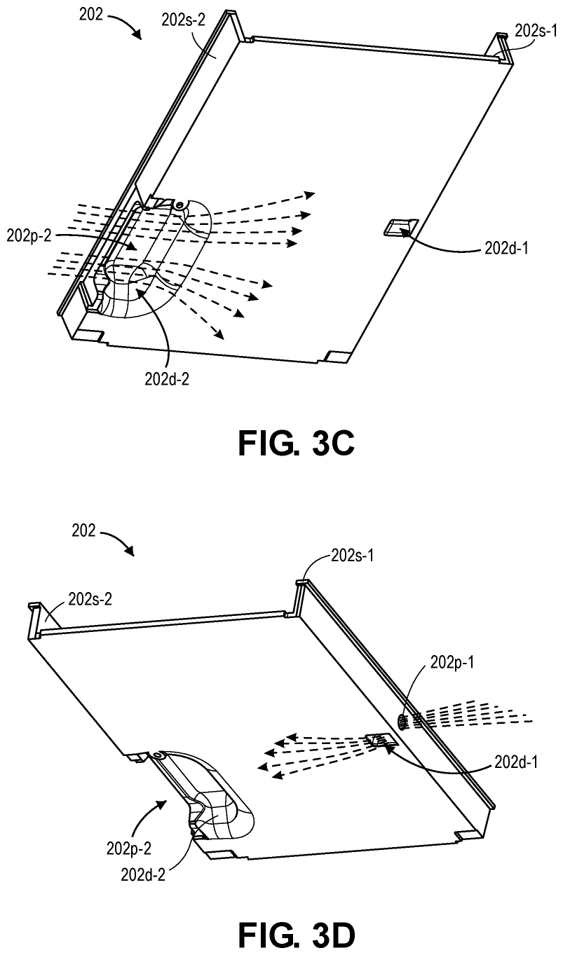

Storage device 200 comprises an enclosure cover 202 (“cover 202”) coupled to an enclosure base 204 (“base 204”). According to an embodiment, cover 202 comprises a first inlet port 202p-1 through a first lateral sidewall 202s-1 and a first cooling duct 202d-1 at least in part coincident with the first inlet port 202p-1, where the first cooling duct 202d-1 is configured to direct and guide airflow laterally (e.g., side-to-side) from the first inlet port 202p-1 to below the cover 202 to the PCB 210 (see, e.g., FIG. 3D). According to an embodiment, cover 202 further comprises at least one second inlet port 202p-2 through a second lateral sidewall 202s-2 opposing the first lateral sidewall, and a second cooling duct 202d-2 at least in part coincident with the second inlet port 202p-2. The second cooling duct 202d-2 is configured to cover an electronic component 210-1 (FIG. 5C) extending from the PCB 210 and to direct and guide airflow laterally from the second inlet port 202p-2 around the electronic component 210-1 to below the cover 202 to the PCB 210 (see, e.g., FIG. 3C).

FIG. 3A is a top perspective view illustrating a top cover of SSD device of FIGS. 2A-2B, FIG. 3B is a top perspective view illustrating a top cover of SSD device of FIGS. 2A-2B, FIG. 3C is a bottom perspective view illustrating a top cover of SSD device of FIGS. 2A-2B, and FIG. 3D is a bottom perspective view illustrating a top cover of SSD device of FIGS. 2A-2B, all according to embodiments. Illustrated further here are the first inlet port 202p-1 (see, e.g., FIG. 3B) through the first lateral sidewall 202s-1 and the coincident first cooling duct 202d-1 (see, e.g., FIG. 3A) of cover 202. As discussed, the first cooling duct 202d-1 is configured to direct airflow laterally from the first inlet port 202p-1 to below the cover 202 to the PCB 210 (see, e.g., FIG. 3D), whereby the placement of the first cooling duct 202d-1 and first inlet port 202p-1 may vary from implementation to implementation based, for example, on PCB hot spot target(s) (for non-limiting examples, controller, NAND, and the like). Cooling duct 202d-1, 202d-2 count, opening size, and placement may vary from implementation to implementation based, for non-limiting examples, on cooling performance goals and in view structural properties (e.g., shock, vibration, thermal cycle, etc.) and electromagnetic compatibility (“EMC”) performance and the like. Furthermore, according to embodiments the airflow direction may be adjusted by complementary design and placement of PCB 210 components, as well as by complementary placement of thermal interface material (“TIM”, e.g., which conducts heat between two or more mating surfaces) according to a detail design.

As discussed and according to an embodiment, the second cooling duct 202d-2 of the cover 202 is configured to cover an electronic component 210-1 (FIG. 5C) extending from the PCB 210 and to direct airflow laterally from the second inlet port 202p-2 around the electronic component 210-1 to below the cover 202 to the PCB 210 (see, e.g., FIG. 3C). For example, PCB 210 of storage device 200 may include an electronic capacitor (see, e.g., power loss capacitor 174 of FIG. 1) that may be a relatively large electronic component that therefore extends from the main board of PCB 210. Here, cooling duct 202d-2 may be placed wherever a relatively oversized extending PCB component may be positioned, and may be structurally and/or aerodynamically configured to guide airflow around such a component accordingly.

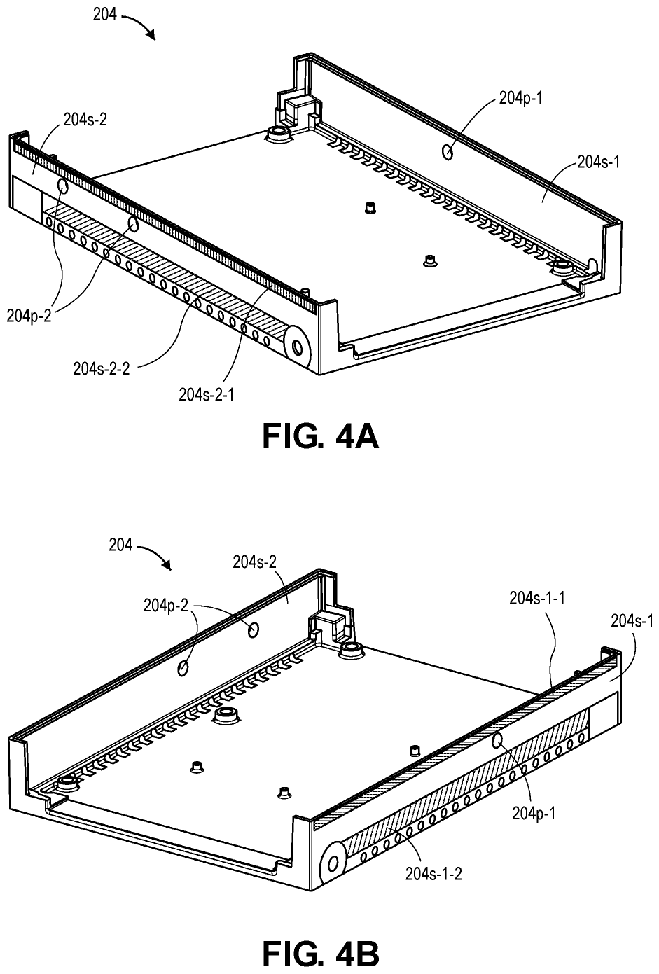

FIG. 4A is a perspective view illustrating a bottom base of SSD device of FIGS. 2A-2B, and FIG. 4B is a perspective view illustrating a bottom base of SSD device of FIGS. 2A-2B, both according to embodiments. Shown here is the base 204 comprising a first inlet port 204p-1 through a first lateral sidewall 204s-1 of the base 204 and which is positioned to be substantially coincident with the first inlet port of the cover 202p-1. According to an embodiment, the base 204 further comprises at least one second inlet port 204p-2 through a second lateral sidewall 204s-2 of the base 204 and which is positioned to be substantially coincident with the second inlet port 202p-1 of the cover 202. According to an embodiment, one or more inlet port 204p-1, 204p-2 of base 204 may be augmented with a chamfer feature at the hole edge to increase air velocity.

FIG. 4A further illustrates a first specification-restricted area 204s-2-1 of the second lateral sidewall 204s-2 of the base 204 and a second specification-restricted area 204s-2-2 of the second lateral sidewall 204s-2 of the base 204, according to which the at least one second inlet port 204p-2 of the base 204 is positioned between to avoid such restricted areas. Similarly, FIG. 4B further illustrates a first specification-restricted area 204s-1-1 of the first lateral sidewall 204s-1 of the base 204 and a second specification-restricted area 204s-1-2 of the first lateral sidewall 204s-1 of the base 204, according to which the first inlet port 204p-1 of the base 204 is positioned between to avoid those restricted areas. For example, the E3.S 2T (short) and E3.L 2T (long) (both having 16.8 millimeter max thickness form factor) specifications specify that each of the first specification-restricted areas 204s-1-1, 204s-2-1 of their respective sidewall 204s-1, 204s-2 are reserved as electrical grounding surface areas. Similarly, the E3.S 2T and E3.L 2T specifications specify that each of the second specification-restricted areas 204s-1-2, 204s-2-2 of their respective sidewall 204s-1, 204s-2 are reserved as riding surface areas for positioning of device carriers/installation structures associated with a given storage device 200.

FIG. 5A is a perspective view illustrating an SSD device assembly defining cross-sections, FIG. 5B is a first cross-sectional perspective view illustrating the SSD device assembly of FIG. 5A, FIG. 5C is a second cross-sectional perspective view illustrating the SSD device assembly of FIG. 5A, FIG. 5D is a third cross-sectional perspective view illustrating the SSD device assembly of FIG. 5A, and FIG. 5E is a fourth cross-sectional perspective view illustrating the SSD device assembly of FIG. 5A, all according to embodiments. Collectively, FIGS. 5A-5E further illustrate the foregoing cooling duct/inlet features.

Thus, FIG. 5B illustrates a first cross-section 5B-5B of storage device 200, sectioning through a second inlet port 204p-2 of the base 204, and a second inlet port 202p-2 and corresponding second cooling duct 202d-2 of the cover 202 of storage device 200, including some of the airflow-directing structural contour (e.g., laterally and longitudinally) of the inside of second cooling duct 202d-2. FIG. 5C illustrates a second cross-section 5C-5C of storage device 200, sectioning through the second lateral sidewall 204s-2 of the base 204, and the second inlet port 202p-2 and corresponding second cooling duct 202d-2 of the cover 202, including some of the airflow-directing structural contour of the inside of second cooling duct 202d-2 around the electronic component 210-1 of PCB 210. FIG. 5D illustrates a third cross-section 5D-5D of storage device 200, again sectioning through a second inlet port 204p-2 of the base 204, and the second inlet port 202p-2 and corresponding second cooling duct 202d-2 of the cover 202, including some of the airflow-directing structural contour (primarily laterally) of the inside of second cooling duct 202d-2, directing airflow to PCB 210 (electronic component 210-1 removed in this view). Finally, FIG. 5E illustrates a fourth cross-section 5E-5E of storage device 200, sectioning through the first inlet port 204p-1 of the base 204 and the first inlet port 202p-1 and corresponding first cooling duct 202d-1 of the cover 202, including some of the airflow-directing structural contour of the inside of second cooling duct 202d-1, directing airflow to PCB 210.

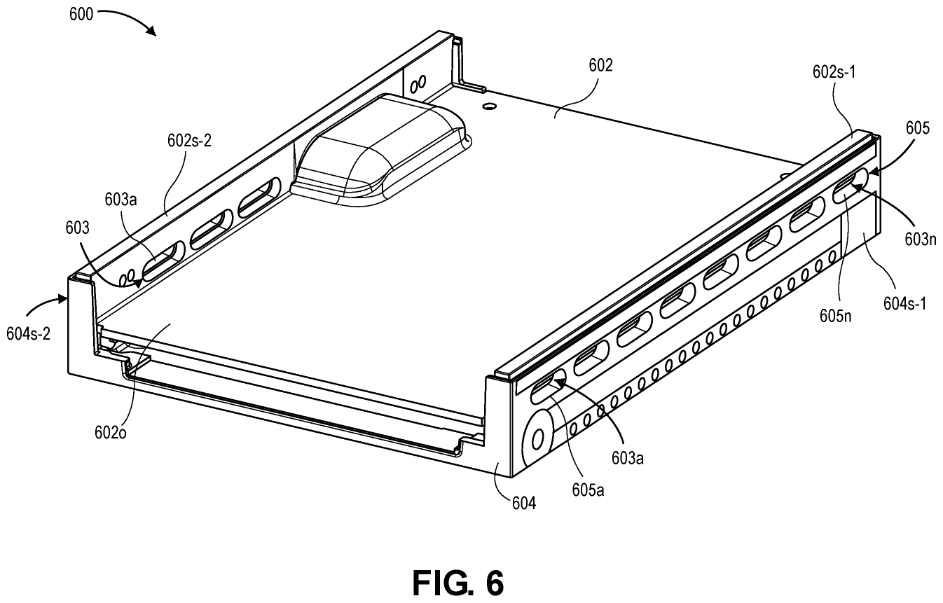

FIG. 6 is a perspective view illustrating an SSD device assembly with cooling ventilation features, according to an embodiment. An electronic storage device such as illustrated storage device 600 is configured to comprise one or more printed circuit board such as PCB 210 of FIGS. 5B-5E (see also, e.g., the components of SSD 152 of FIG. 1) within a device enclosure described hereafter. According to an embodiment, storage device 600 comprises a PCB including non-volatile memory. Similarly, and according to an embodiment, storage device 600 comprises a PCB including NAND (NOT AND) flash memory. Furthermore, and according to an embodiment, storage device 600 is a solid-state drive (SSD) storage device (see, e.g., SSD 152 of FIG. 1).

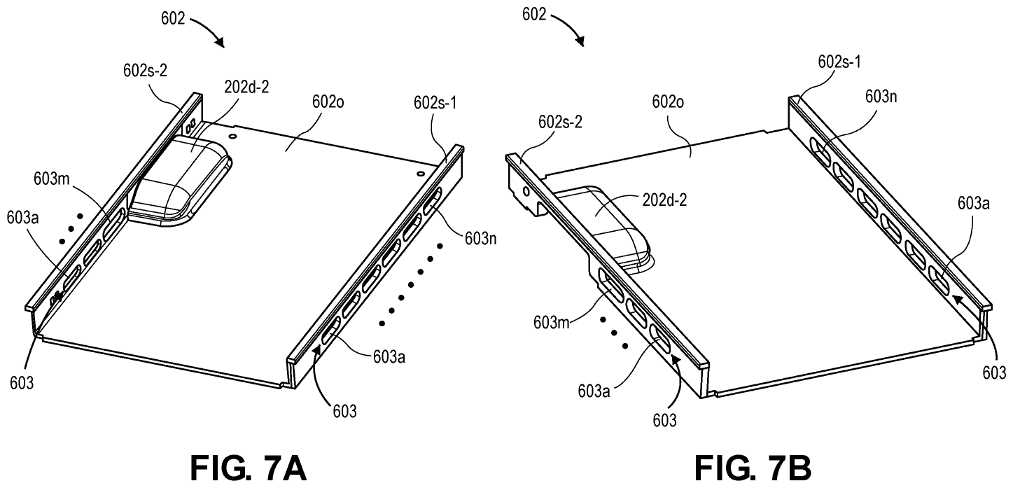

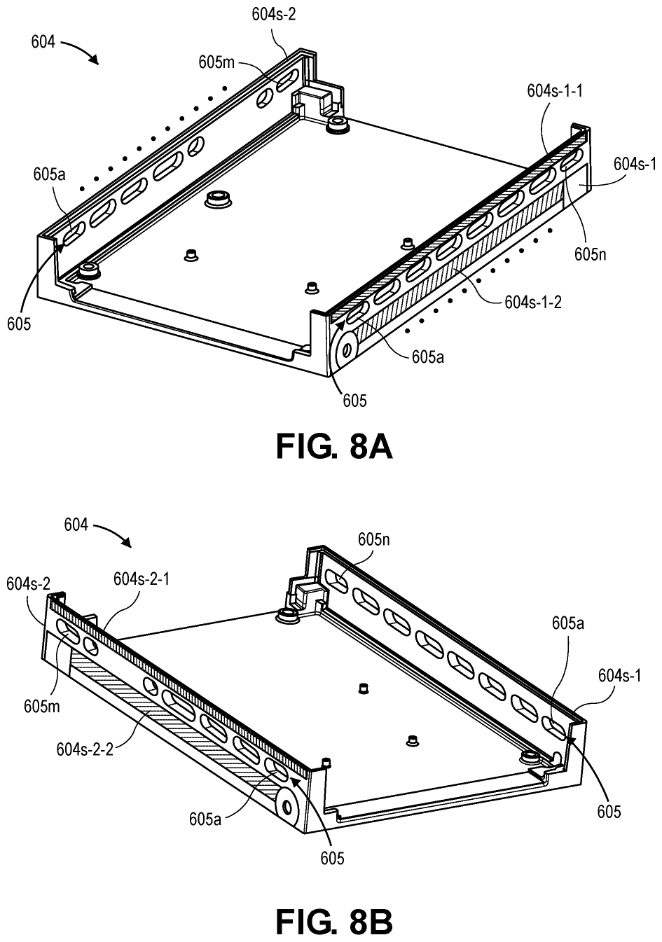

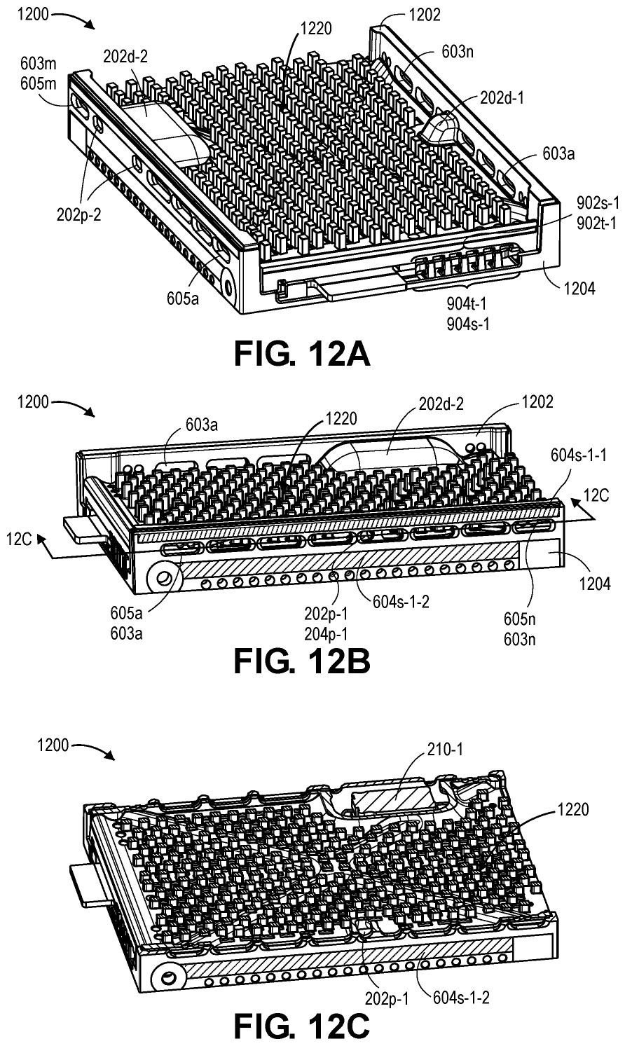

Storage device 600 comprises an enclosure cover 602 (“cover 602”) coupled to an enclosure base 604 (“base 604”). According to an embodiment, cover 602 comprises a first row 603 of first ventilation slots 603a-603n, through a first lateral sidewall 602s-1 of the cover 602, configured to direct airflow generally laterally over an outer side 6020 of the cover 602. Likewise, according to an embodiment the cover 602 comprises second row 603 of second ventilation slots 603a-603m, through a second lateral sidewall 602s-2 of the cover 602 (see, e.g., FIGS. 7A-7B). Similarly, the base 604 comprises a first row 605 of first ventilation slots 605a-605n, through a first lateral sidewall 604s-1 of the base 604 and substantially coincident with the first ventilation slots 603a-603n of the cover 602, configured to direct airflow generally laterally over the outer side 6020 of the cover 602. Here also, according to an embodiment the base 604 comprises a second row 605 of second ventilation slots 605a-605m, through a second lateral sidewall 604s-2 of the base 604 (see, e.g., FIGS. 8A-8B), and substantially coincident with the second ventilation slots 603a-603m of the cover 602. The utilization of such ventilation slots 603a-603n, 605a-605n to direct airflow over the cover 602 is discussed in more detail elsewhere herein, such as in reference to FIGS. 12A-12C.

FIG. 7A is a perspective view illustrating a top cover of SSD device of FIG. 6, and FIG. 7B is a perspective view illustrating the top cover of SSD device of FIG. 6, both according to embodiments. As discussed, cover 602 comprises a row 603 of ventilation slots through one or both of the first and second lateral sidewall 602s-1, 602s-2, which are configured to direct airflow over the outer side 6020 of the cover 602. In FIGS. 7A-7B, first lateral sidewall 602s-1 of cover 602 is depicted with a row 603 of ventilation slots 603a-603n, where n represents an arbitrary number of slots that may vary from implementation to implementation. Furthermore, second lateral sidewall 602s-2 of cover 602 is depicted with a row 603 of ventilation slots 603a-603m, where m represents an arbitrary number of slots that may vary from implementation to implementation. With implementations in which a second cooling duct is present, such as second cooling duct 202d-2 (see, e.g., FIGS. 2A-3D), n and m are likely unequal due to the presence of the second cooling duct 202d-2.

FIG. 8A is a perspective view illustrating a bottom base of SSD device of FIG. 6, and FIG. 8B is a perspective view illustrating the bottom base of SSD device of FIG. 6, all according to embodiments. As discussed, base 604 comprises a row 605 of ventilation slots through one or both of the first and second lateral sidewall 604s-1, 604s-2, which are configured to direct airflow over the outer side 6020 (FIGS. 7A-7B) of the cover 602. In FIGS. 8A-8B, first lateral sidewall 604s-1 of base 604 is depicted with a row 605 of ventilation slots 605a-605n, where n represents an arbitrary number of slots that may vary from implementation to implementation. Furthermore, second lateral sidewall 605s-2 of base 604 is depicted with a row 605 of ventilation slots 605a-605m, where m represents an arbitrary number of slots that may vary from implementation to implementation. As discussed and according to an embodiment, the row 605 of ventilation slots 605a-605n through the first lateral sidewall 604s-1 of the base 604 are positioned between a first specification-restricted area 604s-1-1 and a second specification-restricted area 604s-1-2 of the of the first lateral sidewall 604s-1 of the base 604. Likewise, the row 605 of ventilation slots 605a-605m through the second lateral sidewall 604s-2 of the base 604 are positioned between a first specification-restricted area 604s-2-1 and a second specification-restricted area 604s-2-2 of the of the second lateral sidewall 604s-2 of the base 604.

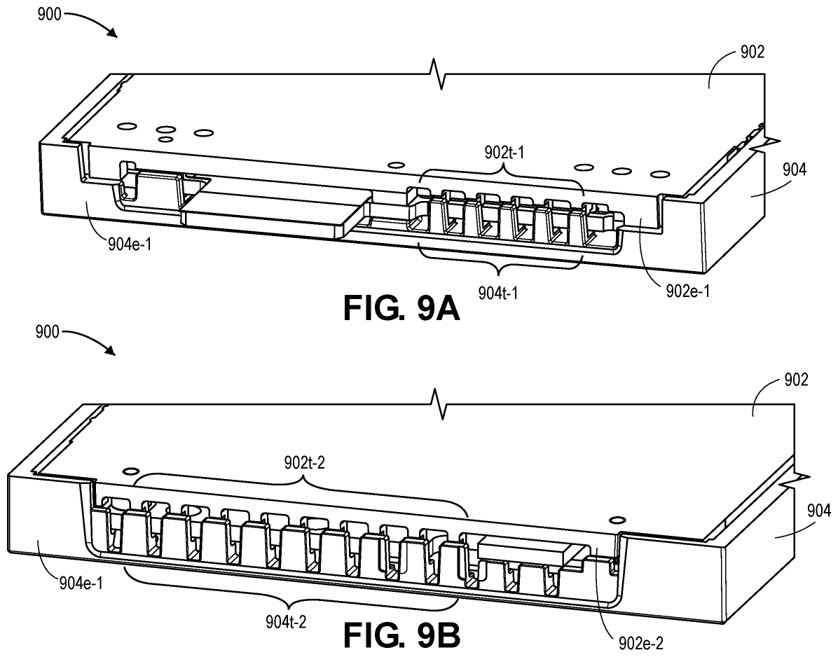

FIG. 9A is a perspective view illustrating a first end of an SSD device assembly with cooling ventilation features, and FIG. 9B is a perspective view illustrating a second end of an SSD device assembly with cooling ventilation features, both according to embodiments. Storage device 900 comprises an enclosure cover 902 (“cover 902”) coupled to an enclosure base 904 (“base 904”). According to an embodiment, the cover 902 comprises a first series of tooth structures 902t-1 separated by slits 902s-1 through a first end wall 902e-1 of the cover 902 (e.g., the host connector end), and the base 904 comprises a first series of tooth structures 904t-1 separated by slits 904s-1 through a first end wall 904e-1 of the base 904 (e.g., the host connector end). Each tooth structure of the first series of tooth structures 904t-1 of the base 904 mechanically interfaces with a corresponding tooth structure of the first series of tooth structures 902t-1 of the cover 902. Furthermore and according to an embodiment, the cover 902 further comprises a second series of tooth structures 902t-2 separated by slits 902s-2 through a second end wall 902e-2 of the cover 902 (e.g., the LED (light-emitting diode) end) opposing the first end wall 902e-1 of the cover 902, and the base 904 further comprises a second series of tooth structures 904t-2 separated by slits 904s-2 through a second end wall 904e-2 of the base 904 (e.g., the LED end), opposing the first end wall 904e-1 of the base 904. Each tooth structure of the second series of tooth structures 904t-2 of the base 904 mechanically interfaces with a corresponding tooth structure of the second series of tooth structures 902t-2 of the cover 902.

According to an embodiment, the slits 902s-1, 902s-2 through the first end wall 902e-1 and the second end wall 902e-2 of the cover 902 are approximately 2 millimeters wide laterally, and the slits 904s-1, 904s-2 through the first end wall 904e-1 and the second end wall 904e-2 of the base 904 are similarly approximately 2 millimeters wide laterally, i.e., sufficiently small enough for mitigating electrostatic discharge (ESD), whereby electrical discharge energy can flow into big openings and shock the electronic components, while still enabling sufficient cooling airflow into and through the storage device 900. ESD, sometimes referred to as “static electricity”, is a momentary flow of electrical current between two differently-charged objects when brought into contact or even when brought close together. It is well-known that ESD can cause damage to and even failure of solid-state electronics components such as integrated circuits, which can suffer permanent damage when subjected to high voltages. Thus, sensitive components need to be protected from ESD.

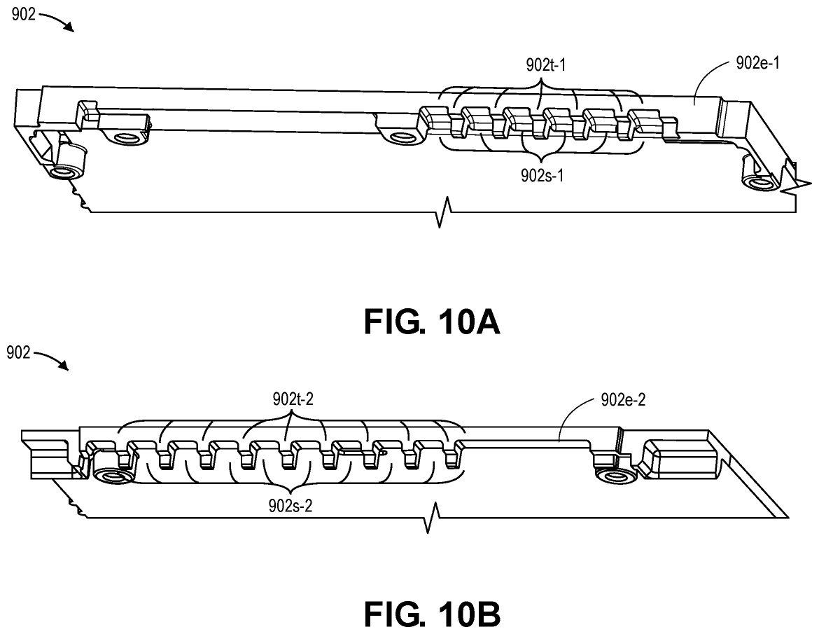

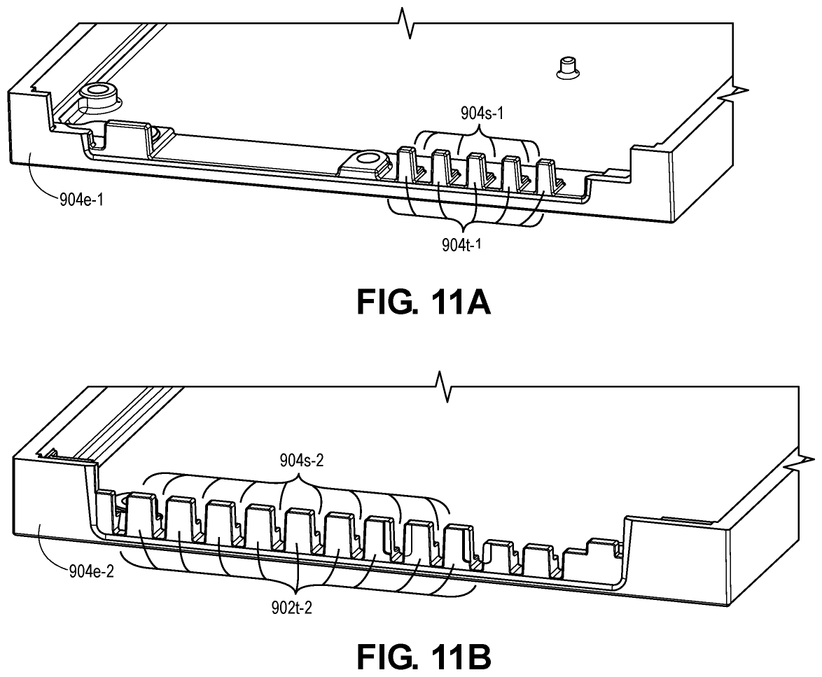

FIG. 10A is a perspective view illustrating the first end of a top cover of SSD device assembly of FIGS. 9A-9B, and FIG. 10B is a perspective view illustrating the second end of the top cover of SSD device assembly of FIGS. 9A-9B, both according to embodiments. As discussed and as depicted in FIG. 10A, according to an embodiment cover 902 comprises a first series of tooth structures 902t-1 separated by slits 902s-1, at one first end wall 902e-1 of the cover 902. Similarly and as depicted in FIG. 10B, according to an embodiment cover 902 further comprises a second series of tooth structures 902t-2 separated by slits 902s-2, at one second end wall 902e-2 of the cover 902. According to an embodiment, each tooth structure of the first and second series of tooth structures 902t-1, 902t-2 of the cover 902 comprises a step structure, as depicted in FIGS. 10A-10B, configured for mechanically interfacing with the corresponding tooth structure of the first and second series of tooth structures 904t-1, 904t-2 (FIGS. 9A-9B, 11A-11B) of the base 904.

FIG. 11A is a perspective view illustrating the first end of a bottom base of SSD device assembly of FIGS. 9A-9B, and FIG. 11B is a perspective view illustrating the second end of the bottom base of SSD device assembly of FIGS. 9A-9B, both according to embodiments. As discussed and as depicted in FIG. 11A, according to an embodiment base 904 comprises a first series of tooth structures 904t-1 separated by slits 904s-1, at one first end wall 904e-1 of the base 904. Similarly and as depicted in FIG. 11B, according to an embodiment base 904 further comprises a second series of tooth structures 904t-2 separated by slits 904s-2, at one second end wall 904e-2 of the base 904. According to an embodiment, each tooth structure of the first and second series of tooth structures 904t-1, 904t-2 of the base 904 comprises a step structure, as depicted in FIGS. 11A-11B, configured for mechanically interfacing with the corresponding tooth structure of the first and second series of tooth structures 902t-1, 902t-2 (FIGS. 9A-9B, 10A-10B) of the cover 902.

With known prior approaches to SSDs, small holes are implemented through the enclosure end walls for air ventilation purposes to meet thermal performance requirements. The manufacturing of such small holes required machining (e.g., computer numerical control, or “CNC”, machining), requiring a significant material cost increase. By contrast, use of the tooth-slit structures 902t-1 with 902s-1, 902t-2 with 902s-2 for the cover 902 and the tooth-slit structures 904t-1 with 904s-1, 904t-2 with 904s-2 for the base 904, enables manufacturing of each of the cover 902 and the base 904 by a casting (e.g., diecasting) process absent (or without requiring) machining, e.g., the machining of tiny ventilation holes. Thus, less costly cover 902 and base 904 structures may be manufactured.

FIG. 12A is an end perspective view illustrating a solid-state storage device, FIG. 12B is a side perspective view illustrating the solid-state storage device of FIG. 12A, and FIG. 12C is a cross-sectional perspective view illustrating the solid-state storage device of FIG. 12A, all according to embodiments. Storage device 1200 illustrates a combination of the cooling features described in more detail elsewhere herein. For example, storage device 1200 is depicted as comprising a cover 1202 over a base 1204 to which a PCB (see, e.g., PCB 210 of FIGS. 5B-5E) is mounted or in which a PCB is otherwise housed. A storage device (e.g., SSD) such as storage device 1200 may be implemented with the first inlet duct 202d-1, and associated first inlet port 202p-1 of cover 202 and first inlet port 204p-1 of base 204 (see, also e.g., FIGS. 2A-5E), and/or the second inlet duct 202d-2 such as over a PCB component 210-1 (see also, e.g., FIG. 5C), and associated second inlet port 202p-2 of cover 202 and second inlet port 204p-2 of base 204 (see also, e.g., FIGS. 2A-5E).

Furthermore, a storage device such as storage device 1200 may be implemented with the first and/or second row 603 of ventilation slots 603a-603n, 603a-603m of cover 602 (see, also e.g., FIGS. 6-7B), and/or the first and/or second row 605 of ventilation slots 605a-605n, 605a-605m of base 604 (see, also e.g., FIGS. 6, 8A-8B), positioned between first specification-restricted area 604s-1-1 and second specification-restricted area 604s-1-2 on one side and/or between first specification-restricted area 604s-2-1 and second specification-restricted area 604s-2-2 on the other side, and which are configured to direct airflow generally laterally over the outer side 6020 (see, e.g., FIGS. 6-7B) of the cover 602, 1202. According to an embodiment, storage device 1200 comprises an outer side of cover 1202 which further comprises a grouping or array of heatsink structures 1220 extending from a main body of cover 1202. Thus, directing the airflow across the outer side 6020 of the cover 1202 includes directing airflow through the ventilation slots 603a-603n and/or 603a-603m of cover 602 and the ventilation slots 605a-605n and/or 605a-605m of base 604 across the array of heatsink structures 1220 thereby enhancing or augmenting the storage device 1200 and corresponding PCB 210 cooling process.

Still further, a storage device such as storage device 1200 may be implemented with the first and/or second tooth structures 902t-1 with slits 902s-1, tooth structures 902t-2 with slits 902s-2 of the cover 1202 (see also, e.g., FIGS. 9A-10B), and the first and/or second tooth structures 904t-1 with slits 904s-1, tooth structures 904t-2 with slits 904s-2 of the base 1204 (see also, e.g., FIGS. 9A, 11A-11B), configured to enable cost effective end-to-end airflow through storage device 1200 while mitigating ESD risk.

### Method of Assembling a Data Storage Device

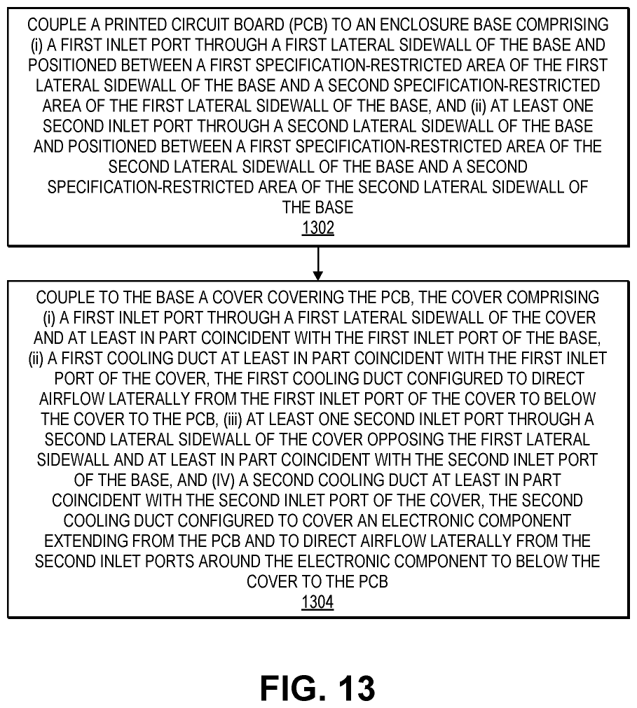

FIG. 13 is a flow diagram illustrating a method of assembling a data storage device, according to an embodiment. For example, the method of FIG. 13 may be implemented to assemble a storage device 200 as exemplified in the illustrations and descriptions corresponding to FIGS. 2A-2B, a storage device 600 as exemplified in the illustrations and descriptions corresponding to FIG. 6, a storage device 900 as exemplified in the illustrations and descriptions corresponding to FIGS. 9A-9B, and a storage device 1200 as exemplified in the illustrations and descriptions corresponding to FIGS. 12A-12C.

At block 1302, couple a printed circuit board (PCB) to an enclosure base comprising (i) a first inlet port through a first lateral sidewall of the base and positioned between a first specification-restricted area of the first lateral sidewall of the base and a second specification-restricted area of the first lateral sidewall of the base, and (ii) at least one second inlet port through a second lateral sidewall of the base and positioned between a first specification-restricted area of the second lateral sidewall of the base and a second specification-restricted area of the second lateral sidewall of the base. For example, PCB 210 (FIGS. 5B-5E) is coupled to an enclosure base 204 (FIGS. 2A-2B, 4A-4B, 5B-5E), 604 (FIGS. 6, 8A-8B), 904 (FIGS. 9A-9B, 11A-11B), 1204 (FIGS. 12A-12B) comprising (i) a first inlet port 204p-1 (FIGS. 2A-2B, 4A-4B, 5B-5E) through a first lateral sidewall 204s-1 (FIGS. 2A-2B, 4A-4B, 5B-5E) of the base 204, 604, 904, 1204 and positioned between a first specification-restricted area 604s-1-1 (FIGS. 8A-8B) of the first lateral sidewall 604s-1 (FIGS. 8A-8B) of the base 604 and a second specification-restricted area 604s-1-2 (FIGS. 8A-8B) of the first lateral sidewall 604s-1 of the base 604, and (ii) at least one second inlet port 204p-2 (FIGS. 2A-2B, 4A-4B, 5B-5E) through a second lateral sidewall 204s-2 (FIGS. 2A-2B, 4A-4B, 5B-5E) of the base 204, 604, 904, 1204 and positioned between a first specification-restricted area 604s-2-1 (FIGS. 8A-8B) of the second lateral sidewall 604s-2 (FIGS. 8A-8B) of the base 204, 604, 904, 1204 and a second specification-restricted area 604s-2-2 (FIGS. 8A-8B) of the second lateral sidewall 604s-2 of the base 204, 604, 904, 1204.

At block 1304, couple to the base a cover covering the PCB, the cover comprising (i) a first inlet port through a first lateral sidewall of the cover and at least in part coincident with the first inlet port of the base, (ii) a first cooling duct at least in part coincident with the first inlet port of the cover, the first cooling duct configured to direct airflow laterally from the first inlet port of the cover to below the cover to the PCB, (iii) at least one second inlet port through a second lateral sidewall of the cover opposing the first lateral sidewall and at least in part coincident with the second inlet port of the base, and (iv) a second cooling duct at least in part coincident with the second inlet port of the cover, the second cooling duct configured to cover an electronic component extending from the PCB and to direct airflow laterally from the second inlet ports around the electronic component to below the cover to the PCB. For example, cover 202 (FIGS. 2A-2B, 3A-3D, 5B-5E), 604 (FIGS. 6, 7A-7B), 904 (FIGS. 9A-9B, 10A-10B), 1204 (FIGS. 12A-12B) is coupled to base 204, 604, 904, 1204 over the PCB 210, the cover 202, 602, 902, 1202 comprising (i) a first inlet port 202p-1 (FIGS. 2A-2B, 3A-3D, 5B-5E) through a first lateral sidewall 202s-1 (FIGS. 2A-2B, 3A-3D, 5B-5E) of the cover 202, 602, 902, 1202 and at least in part coincident with the first inlet port 204p-1 of the base 204, 604, 904, 1204, (ii) a first cooling duct 202d-1 (FIGS. 2A-2B, 3A-3D, 5B-5E) at least in part coincident with the first inlet port 202p-1 of the cover 202, 602, 902, 1202, the first cooling duct 202d-1 configured to direct airflow laterally from the first inlet port 202p-1 of the cover 202, 602, 902, 1202 to below the cover to the PCB 210, (iii) at least one second inlet port 202p-2 (FIGS. 2A-2B, 3A-3D, 5B-5E) through a second lateral sidewall 202s-2 (FIGS. 2A-2B, 3A-3D, 5B-5E) of the cover 202, 602, 902, 1202 opposing the first lateral sidewall 202s-1 and at least in part coincident with the second inlet port 204p-2 of the base 204, 604, 904, 1204, and (iv) a second cooling duct 202d-2 (FIGS. 2A-2B, 3A-3D, 5B-5E) at least in part coincident with the second inlet port 202p-2 of the cover 202, 602, 902, 1202, the second cooling duct 202d-2 configured to cover an electronic component 210-1 (FIG. 5C) extending from the PCB 210 and to direct airflow laterally from the second inlet port 202p-2 around the electronic component 210-1 to below the cover 202, 602, 902, 1202 to the PCB 210.

As described throughout herein, for a storage device such as an SSD, implementation of one or more cooling features described herein enables cost-effective (e.g., avoiding machining operations) enhanced airflow, ventilation, and cooling (e.g., using inlet ports and ducts and/or rows of ventilation slots for enabling lateral airflow to a PCB and/or over a cover/heatsinks) of such a device, within constraints that may be imposed by standard specifications to which the device may correspond (e.g., the grounding and riding surfaces required of the E3 family of specifications for SSDs), and while mitigating ESD risks associated with openings through ends (e.g., LED end, host connector end) of such a device.

### Physical Description of an Illustrative Operating Context

Embodiments may be used in the context of electronic devices including digital data storage devices (DSDs), such as a solid-state drives (SSDs). Thus, FIG. 1 is a block diagram illustrating a generic SSD architecture 150, for an example operating context of an electronic device with which embodiments of the invention may be implemented. The generic SSD architecture 150 depicts an SSD 152 communicatively coupled with a host 154 through a primary communication interface 156. SSD implementations are not limited to a configuration as depicted in FIG. 1, as embodiments may be implemented with SSD configurations other than that illustrated in FIG. 1 and/or with electronic devices other than SSDs.

Host 154 broadly represents any type of computing hardware, software, or firmware (or any combination of the foregoing) that makes, among others, data I/O requests or calls to one or more memory device. For example, host 154 may be an operating system executing on a computer, a tablet, a mobile phone, or generally any type of computing device that contains or interacts with storage memory. The primary interface 156 coupling host 154 to SSD 152 may be, for example, a storage system's internal bus or a communication cable or a wireless communication link, or the like.

The example SSD 152 illustrated in FIG. 1 includes an interface 160, a controller 162 (e.g., a controller having firmware logic therein), an addressing 164 function block, data buffer cache 166, and one or more non-volatile memory (NVM) components 170a, 170b-170n, where n represents an arbitrary number of NVM components that may vary from implementation to implementation.

Interface 160 is a point of interaction between components, namely SSD 152 and host 154 in this context, and is applicable at the level of both hardware and software. This enables a component to communicate with other components via an input/output (IO) system and an associated protocol. A hardware interface is typically described by the mechanical, electrical and logical signals at the interface and the protocol for sequencing them. Some non-limiting examples of common and standard interfaces include SCSI (Small Computer System Interface), SAS (Serial Attached SCSI), and SATA (Serial ATA).

An SSD 152 includes a controller 162, which incorporates the electronics that bridge the non-volatile memory components (e.g., NAND flash) to the host, such as non-volatile memory 170a, 170b-170n to host 154. The controller is typically an embedded processor that executes firmware-level code and can be a significant factor in SSD performance.

Controller 162 interfaces with non-volatile memory 170a, 170b-170n via an addressing 164 function block. The addressing 164 function operates, for example, to manage mappings between logical block addresses (LBAs) from the host 154 to a corresponding physical block address on the SSD 152, namely, on the non-volatile memory 170a, 170b-170n of SSD 152. Because the non-volatile memory page and the host sectors are different sizes, an SSD has to build and maintain a data structure that enables it to translate between the host writing data to or reading data from a sector, and the physical non-volatile memory page on which that data is actually placed. This table structure or “mapping” may be built and maintained for a session in the SSD's volatile memory 172, such as DRAM or some other local volatile memory component accessible to controller 162 and addressing 164. Alternatively, the table structure may be maintained more persistently across sessions in the SSD's non-volatile memory such as non-volatile memory 170a, 170b-170n.

Addressing 164 interacts with data buffer cache 166, in addition to non-volatile memory 170a, 170b-170n. Data buffer cache 166 of an SSD 152 typically uses DRAM as a cache, similar to the cache in hard disk drives. Data buffer cache 166 serves as a buffer or staging area for the transmission of data to and from the non-volatile memory components, as well as serves as a cache for speeding up future requests for the cached data. Data buffer cache 166 is typically implemented with volatile memory so the data stored therein is not permanently stored in the cache, i.e., the data is not persistent.

Finally, SSD 152 includes the one or more non-volatile memory 170a, 170b-170n components. For a non-limiting example, the non-volatile memory components 170a, 170b-170n may be implemented as flash memory (e.g., NAND or NOR flash), or other types of solid-state memory available now or in the future. The non-volatile memory 170a, 170b-170n components are the actual memory electronic components on which data is persistently stored. The non-volatile memory 170a, 170b-170n components of SSD 152 can be considered the analogue to the hard disks in hard-disk drive (HDD) storage devices.

Furthermore, references herein to a data storage device may encompass a multi-medium storage device (or “multi-medium device”, which may at times be referred to as a “multi-tier device” or “hybrid drive”). A multi-medium storage device refers generally to a storage device having functionality of both a traditional HDD (see, e.g., HDD 100) combined with an SSD (see, e.g., SSD 150) using non-volatile memory, such as flash or other solid-state (e.g., integrated circuits) memory, which is electrically erasable and programmable. As operation, management and control of the different types of storage media typically differ, the solid-state portion of a hybrid drive may include its own corresponding controller functionality, which may be integrated into a single controller along with the HDD functionality. A multi-medium storage device may be architected and configured to operate and to utilize the solid-state portion in a number of ways, such as, for non-limiting examples, by using the solid-state memory as cache memory, for storing frequently-accessed data, for storing I/O intensive data, for storing metadata corresponding to payload data (e.g., for assisting with decoding the payload data), and the like. Further, a multi-medium storage device may be architected and configured essentially as two storage devices in a single enclosure, i.e., a traditional HDD and an SSD, with either one or multiple interfaces for host connection.

### EXTENSIONS AND ALTERNATIVES

In the foregoing description, embodiments of the invention have been described with reference to numerous specific details that may vary from implementation to implementation. Therefore, various modifications and changes may be made thereto without departing from the broader spirit and scope of the embodiments. Thus, the sole and exclusive indicator of what is the invention, and is intended by the applicants to be the invention, is the set of claims that issue from this application, in the specific form in which such claims issue, including any subsequent correction. Any definitions expressly set forth herein for terms contained in such claims shall govern the meaning of such terms as used in the claims. Hence, no limitation, element, property, feature, advantage or attribute that is not expressly recited in a claim should limit the scope of such claim in any way. The specification and drawings are, accordingly, to be regarded in an illustrative rather than a restrictive sense.

In addition, in this description certain process steps may be set forth in a particular order, and alphabetic and alphanumeric labels may be used to identify certain steps. Unless specifically stated in the description, embodiments are not necessarily limited to any particular order of carrying out such steps. In particular, the labels are used merely for convenient identification of steps, and are not intended to specify or require a particular order of carrying out such steps.

What is claimed is:

1. An electronic storage device comprising:
an enclosure base;
a printed circuit board (PCB) coupled with the base; and
an enclosure cover coupled with the base and covering the PCB, the cover comprising:
a first inlet port through a first lateral sidewall of the cover, and
a first cooling duct at least in part coincident with the first inlet port, the first cooling duct configured to direct airflow laterally from the first inlet port to below the cover to the PCB.

2. The electronic storage device of claim 1, wherein the first cooling duct is further configured to direct airflow from the first inlet port to a target hot spot of the PCB.

3. The electronic storage device of claim 1, wherein:
the cover further comprises a row of ventilation slots, through the first lateral sidewall of the cover, configured to direct airflow over an outer side of the cover; and
the base comprises a row of ventilation slots, through a first lateral sidewall of the base and substantially coincident with the ventilation slots of the cover, configured to direct airflow over the outer side of the cover.

4. The electronic storage device of claim 3, wherein the outer side of the cover comprises a plurality of heatsink structures extending from a main body of the cover.

5. The electronic storage device of claim 1, wherein the base comprises a first inlet port through a first lateral sidewall of the base and substantially coincident with the first inlet port of the cover.

6. The electronic storage device of claim 1, wherein:
the cover further comprises:
at least one second inlet port through a second lateral sidewall of the cover opposing the first lateral sidewall, and
a second cooling duct at least in part coincident with the second inlet port, the second cooling duct configured to cover an electronic component extending from the PCB and to direct airflow laterally from the second inlet port around the electronic component to below the cover to the PCB.

7. The electronic storage device of claim 6, wherein the base comprises at least one second inlet port through a second lateral sidewall of the base and substantially coincident with the second inlet port of the cover.

8. The electronic storage device of claim 7, wherein:
the at least one second inlet port of the base is positioned between a first specification-restricted area of the second lateral sidewall of the base and a second specification-restricted area of the second lateral sidewall of the base; and
the base further comprises a first inlet port through a first lateral sidewall of the base and substantially coincident with the first inlet port of the cover and positioned between a first specification-restricted area of the first lateral sidewall of the base and a second specification-restricted area of the first lateral sidewall of the base.

9. The electronic storage device of claim 6, wherein the base comprises a row of ventilation slots, through the second lateral sidewall of the base, configured to direct airflow over an outer side of the cover and positioned between a first specification-restricted area of the second lateral sidewall of the base and a second specification-restricted area of the second lateral sidewall of the base.

10. The electronic storage device of claim 1, wherein:
the base comprises a first series of tooth structures separated by slits through a first end wall of the base;
the cover comprises a first series of tooth structures separated by slits through a first end wall of the cover; and
each tooth structure of the first series of tooth structures of the base mechanically interfaces with a corresponding tooth structure of the first series of tooth structures of the cover.

11. The electronic storage device of claim 10, wherein:
the base comprises a second series of tooth structures separated by slits through a second end wall of the base opposing the first end wall of the base;
the cover comprises a second series of tooth structures separated by slits through a second end wall of the cover opposing the first end wall of the cover; and
each tooth structure of the second series of tooth structures of the base mechanically interfaces with a corresponding tooth structure of the second series of tooth structures of the cover.

12. The electronic storage device of claim 11, wherein:
each tooth structure of the first and second series of tooth structures of the base comprises a step structure configured for mechanically interfacing with the corresponding tooth structure of the first and second series of tooth structures of the cover; and
each tooth structure of the first and second series of tooth structures of the cover comprises a step structure configured for mechanically interfacing with the corresponding tooth structure of the first and second series of tooth structures of the base.

13. The electronic storage device of claim 11, wherein:
the slits through the first end wall and the second end wall of the base are approximately 2 millimeters wide laterally;
the slits through the first end wall and the second end wall of the cover are approximately 2 millimeters wide laterally.

14. The electronic storage device of claim 10, wherein each of the base and the cover is formed by casting absent machining.

15. The electronic storage device of claim 1, wherein the electronic storage device is a solid-state drive (SSD) storage device.

16. A solid-state storage device comprising:
a printed circuit board (PCB) comprising electronic means for non-volatile data storage;
an enclosure cover coupled with an enclosure base and covering the PCB, the cover comprising:
a first inlet port through a first lateral sidewall of the cover,
a first cooling duct at least in part coincident with the first inlet port, the first cooling duct configured to direct airflow laterally from the first inlet port to below the cover to the PCB,
at least one second inlet port through a second lateral sidewall of the cover opposing the first lateral sidewall, and
a second cooling duct at least in part coincident with the second inlet port, the second cooling duct configured to cover an electronic component extending from the PCB and to direct airflow laterally from the second inlet port around the electronic component to below the cover to the PCB; and
the enclosure base comprising:
a first inlet port through a first lateral sidewall of the base and substantially coincident with the first inlet port of the cover and positioned between a first specification-restricted area of the first lateral sidewall of the base and a second specification-restricted area of the first lateral sidewall of the base, and
at least one second inlet port through a second lateral sidewall of the base and substantially coincident with the second inlet port of the cover and positioned between a first specification-restricted area of the second lateral sidewall of the base and a second specification-restricted area of the second lateral sidewall of the base.

17. The solid-state storage device of claim 16, wherein:
each of the first and second inlet ports of the cover is one of a row of ventilation slots, through the respective first and second lateral sidewall of the cover, configured to direct airflow over an outer side of the cover comprising extending heatsink structures; and
each of the first and second inlet ports of the base is one of a row of ventilation slots, through the respective first and second lateral sidewall of the base, configured to direct airflow over the outer side of the cover.

18. The solid-state storage device of claim 16, wherein:
the base is produced by diecasting without machining, and comprises:
a first series of tooth structures separated by slits through a first end wall of the base, and
a second series of tooth structures separated by slits through a second end wall of the base opposing the first end wall of the base;
the cover is produced by diecasting without machining, and comprises:
a first series of tooth structures separated by slits through a first end wall of the cover, and
a second series of tooth structures separated by slits through a second end wall of the cover opposing the first end wall of the cover;
each tooth structure of the first and second series of tooth structures of the base mechanically interfaces with a corresponding tooth structure of the respective first and second series of tooth structures of the cover.

19. A method of assembling a data storage device, the method comprising:
coupling a printed circuit board (PCB) to an enclosure base comprising (i) a first inlet port through a first lateral sidewall of the base and positioned between a first specification-restricted area of the first lateral sidewall of the base and a second specification-restricted area of the first lateral sidewall of the base, and (ii) at least one second inlet port through a second lateral sidewall of the base and positioned between a first specification-restricted area of the second lateral sidewall of the base and a second specification-restricted area of the second lateral sidewall of the base; and
coupling to the base a cover covering the PCB, the cover comprising (i) a first inlet port through a first lateral sidewall of the cover and at least in part coincident with the first inlet port of the base, (ii) a first cooling duct at least in part coincident with the first inlet port of the cover, the first cooling duct configured to direct airflow laterally from the first inlet port of the cover to below the cover to the PCB, (iii) at least one second inlet port through a second lateral sidewall of the cover opposing the first lateral sidewall and at least in part coincident with the second inlet port of the base, and (iv) a second cooling duct at least in part coincident with the second inlet port of the cover, the second cooling duct configured to cover an electronic component extending from the PCB and to direct airflow laterally from the second inlet ports around the electronic component to below the cover to the PCB.

20. The method of claim 19, further comprising:
prior to coupling the PCB to the base, casting the base; and
prior to coupling the cover to the base, casting the cover.
